(19) United States
(12) Patent Application Publication
(10) Pub. No.: US 2011/0121311 A1
(43) Pub. Date: May 26, 2011

(54) METHOD FOR MANUFACTURING SEMICONDUCTOR SUBSTRATE, METHOD FOR MANUFACTURING SEMICONDUCTOR DEVICE, SEMICONDUCTOR SUBSTRATE, AND SEMICONDUCTOR DEVICE

(75) Inventors: Fumitaka SATO, Itami-shi (JP); Akihiro HACHIGO, Itami-shi (JP); Naoki MATSUMOTO, Itami-shi (JP); Yoko MAEDA, Itami-shi (JP); Seiji NAKAHATA, Itami-shi (JP)

(73) Assignee: SUMITOMO ELECTRIC INDUSTRIES, LTD., Osaka-shi (JP)

(21) Appl. No.: 12/943,545

(22) Filed: Nov. 10, 2010

(30) Foreign Application Priority Data
Nov. 20, 2009 (JP) 2009-265262

(51) Int. Cl. H01L 29/12; H01L 21/18

(52) U.S. Cl. 257/76; 438/458; 257/E21.087; 257/E29.068

(57) ABSTRACT

The present invention provides a method for manufacturing a semiconductor substrate including a low-resistance nitride layer laminated on a substrate, a method for manufacturing a semiconductor device, a semiconductor substrate, and a semiconductor device. A method for manufacturing a semiconductor substrate of the present invention includes the following steps: A nitride substrate having a principal surface and a back surface opposite to the principal surface is prepared. Vapor-phase ions are implanted into the back surface of the nitride substrate. The back surface of the nitride substrate is bonded to a dissimilar substrate to form a bonded substrate. The nitride substrate is partially separated from the bonded substrate to form a laminated substrate including the dissimilar substrate and a nitride layer. The laminated substrate is heat-treated at a temperature over 700° C.

### BACKGROUND OF THE INVENTION

1. Field of the Invention

The present invention relates to a method for manufacturing a semiconductor substrate, a method for manufacturing a semiconductor device, a semiconductor substrate, and a semiconductor device.

2. Description of the Related Art

Nitride substrates such as a gallium nitride (GaN) substrate and the like which have an energy band gap of 3.4 eV and high thermal conductivity attract attention as materials for semiconductor devices such as a short-wavelength optical device, a power electronic device, and the like. Such nitride substrates are expensive. Therefore, Japanese Unexamined Patent Application Publication No. 2006-210660 discloses a method for manufacturing a semiconductor substrate in which a nitride semiconductor thin film with a low dislocation density is formed on a silicon (Si) substrate or a substrate composed of any desired material.

The method for manufacturing a semiconductor substrate described in Japanese Unexamined Patent Application Publication No. 2006-210660 includes the following steps: First, ions are implanted near a surface of a first nitride semiconductor substrate. Then, the surface side of the first nitride semiconductor substrate is laminated on a second substrate. The laminated two substrates are heat-treated. Next, most part of the first nitride semiconductor substrate is separated from the second substrate at an ion-implanted layer as a boundary.

However, the inventors have found that when ions are implanted into a first nitride semiconductor substrate, the resistance of an ion-implanted region is increased. Therefore, the inventors first found that when a semiconductor device is formed using a semiconductor substrate manufactured by the manufacturing method of Japanese Unexamined Patent Application Publication No. 2006-210660, there occurs the problem of complicating a chip structure and failing to achieve sufficient breakdown voltage.

### SUMMARY OF THE INVENTION

Accordingly, it is a first object of the present invention to provide a method for manufacturing a semiconductor substrate including a low-resistance nitride layer bonded to a substrate, and a semiconductor substrate. It is a second object of the present invention to provide a method for manufacturing a semiconductor device with improved quality and a semiconductor device with improved quality.

The inventors keenly investigated a method for manufacturing a semiconductor substrate with good characteristics by forming a fragile region in a nitride substrate by ion implantation, bonding the nitride substrate to another substrate, and then separating the nitride substrate at the fragile region. As a result, it was found that in the step of forming a fragile region in a nitride substrate by ion implantation, the resistance of an ion-implanted region is increased due to residual ions and the influence of ion implantation. Therefore, as a result of intensive research for decreasing the resistance of the nitride substrate after ion implantation, the present invention has been achieved.

A method for manufacturing a semiconductor substrate of the present invention includes the following steps: A nitride substrate having a principal surface and a back surface opposite to the principal surface is prepared. Ions of a light element are implanted into the back surface of the nitride substrate. The back surface of the nitride substrate is bonded to a dissimilar substrate to form a bonded substrate. The nitride substrate is partially separated from the bonded substrate to form a laminated substrate including the dissimilar substrate and a nitride layer. The laminated substrate is heat-treated at a temperature over 700° C.

According to the method for manufacturing a semiconductor substrate of the present invention, heat treatment is performed after ions of a light element are implanted to form a fragile region. Since the ions are of a light element, the implanted ions are easily released through the heat treatment from the nitride layer (residue of the nitride substrate) bonded to the dissimilar substrate without being separated from the nitride substrate. In addition, as a result of keen research of heat treatment conditions for promoting the release of the implanted ions, the inventors have found that heat treatment is performed at a temperature over 700° C. Therefore, the removal of the implanted ions from the nitride layer can be promoted, and thus the resistance of the nitride layer bonded to the dissimilar substrate without being separated from the bonded substrate can be decreased. Therefore, a semiconductor substrate with a low-resistance nitride layer bonded thereto can be manufactured.

The “light element” represents Ar (argon) or less in terms of atomic number. In the method for manufacturing a semiconductor substrate, the heat treatment step is preferably performed at a temperature of 1500° C. or less. This can suppress deterioration of the nitride substrate due to heat treatment.

In the method for manufacturing a semiconductor substrate, the heat treatment step is preferably performed in an atmosphere containing nitrogen (N) atoms.

Consequently, N atoms which constitute the nitride substrate can be suppressed from being released by heat treatment.

In the method for manufacturing a semiconductor substrate, in the ion implantation step, the ions are preferably implanted in a dose of 1×10¹⁷ cm⁻² or more and 1×10¹⁸ cm⁻² or less.

When the dose is 1×10¹⁷ cm⁻² or more, a fragile region can be formed, thereby facilitating separation of the nitride substrate. When the dose is 1×10¹⁸ cm⁻² or less, the lower-resistance nitride layer can be formed by heat treatment. From this viewpoint, the dose is more preferably 2×10¹⁷ cm⁻² or more and 8×10¹⁷ cm⁻² or less.

A method for manufacturing a semiconductor device of the present invention includes a step of manufacturing a semiconductor substrate by the above-described method for manufacturing a semiconductor substrate, a step of forming an epitaxial layer on the semiconductor substrate, and a step of forming an electrode on the epitaxial layer.

According to the method for manufacturing a semiconductor device of the present invention, a semiconductor substrate including a low-resistance nitride layer is provided. Since an epitaxial layer is formed on the nitride layer, complication of a chip structure and a decrease in breakdown voltage can be suppressed.

A semiconductor substrate according to the present invention includes a dissimilar substrate and a nitride layer formed on the dissimilar substrate, the nitride layer having a resistivity of 10 Ω·cm or less.

According to the semiconductor substrate of the present invention, the nitride layer having a low resistivity of 10 Ω·cm or less is provided, and an epitaxial layer with improved quality can be formed on the nitride layer. Therefore, by manufacturing a semiconductor device using the semiconductor substrate, the quality of the semiconductor device can be improved.

A semiconductor device according to the present invention includes the above-described semiconductor substrate, an epitaxial layer formed on the semiconductor substrate, and an electrode formed on the epitaxial layer.

According to the semiconductor device of the present invention, the semiconductor substrate including the low-resistance nitride layer is used, and thus a semiconductor device with improved quality can be realized.

As described above, according to the method for manufacturing a semiconductor substrate of the present invention, a semiconductor substrate including a low-resistance nitride layer laminated thereon can be provided. The semiconductor substrate of the present invention includes the low-resistance nitride layer, and thus an epitaxial layer with improved quality can be formed on the nitride layer. In addition, according to the method for manufacturing a semiconductor device of the present invention, a semiconductor device with improved quality can be provided. The semiconductor device of the present invention includes a semiconductor substrate including a low-resistance nitride layer and thus has improved quality.

### BRIEF DESCRIPTION OF THE DRAWINGS

FIG. 1 is a sectional view schematically showing a semiconductor substrate according to a first embodiment of the present invention.

FIG. 2 is a flow chart showing a method for manufacturing the semiconductor substrate according to the first embodiment of the present invention.

FIG. 3 is a sectional view schematically showing a nitride substrate according to the first embodiment of the present invention.

FIG. 4 is a sectional view schematically showing a state in which ions are implanted into the nitride substrate according to the first embodiment of the present invention.

FIG. 5 is a sectional view schematically showing a dissimilar substrate according to the first embodiment of the present invention.

FIG. 6 is a sectional view schematically showing a state in which the nitride substrate and the dissimilar substrate are bonded together according to the first embodiment of the present invention.

FIG. 7 is a sectional view schematically showing a state in which a portion of the nitride substrate is separated from a bonded substrate according to the first embodiment of the present invention.

FIG. 8 is a sectional view schematically showing a semiconductor device according to a second embodiment of the present invention.

FIG. 9 is a flow chart showing a method for manufacturing the semiconductor device according to the second embodiment of the present invention.

FIG. 10 is a sectional view schematically showing a semiconductor device of Comparative Examples 6 and 7.

### DESCRIPTION OF THE PREFERRED EMBODIMENTS

Embodiments of the present invention are described based on the drawings. In the drawings below, the same or corresponding portions are denoted by the same reference numeral, and a description thereof is not repeated. In the specification, an individual plane is represented by ( ) and a family of planes is represented by { }. A negative index is shown by placing “−” (bar) above a number from a crystallographic viewpoint, but, in the specification, a negative sign is placed before a number.

### First Embodiment

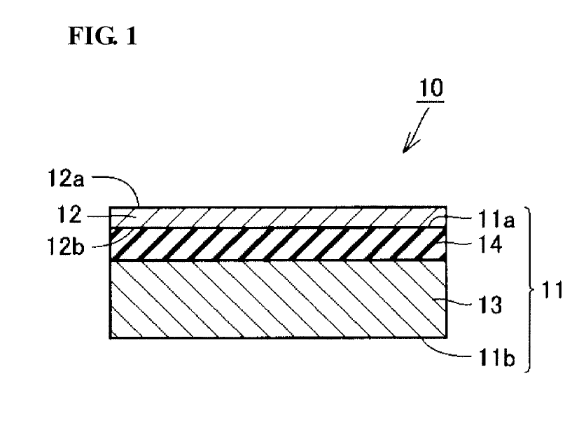

A semiconductor substrate 10 according to a first embodiment of the present invention is described with reference to FIG. 1. As shown in FIG. 1, the semiconductor substrate 10 according to the first embodiment includes a dissimilar substrate 11 and a nitride layer 12 formed on the dissimilar substrate 11.

The dissimilar substrate 11 is dissimilar to a nitride substrate, thus, it is a substrate mainly including a compound different from that of the nitride substrate. For example, when the nitride substrate is composed of GaN, the dissimilar substrate 11 is a substrate other than the GaN substrate. In addition, the dissimilar substrate 11 is not particularly limited as long as a material has a thermal expansion coefficient close to that of the nitride substrate and can resist a semiconductor process temperature. Although the thermal expansion coefficient and the semiconductor process temperature are not particularly limited, the thermal expansion coefficient is preferably ±4×10⁻⁶/K of that of the nitride substrate, and the semiconductor process temperature is preferably 1500° C. or less and more preferably 1200° C. or less.

The dissimilar substrate 11 shown in FIG. 1 includes, for example, a substrate 13 and a layer 14 formed on the substrate 13. The substrate 13 is, for example, a silicon (Si) substrate. The layer 14 is, for example, a silicon dioxide (SiO₂) layer. The dissimilar substrate 11 has a principal surface 11a and a back surface 11b opposite to the principal surface 11a.

The dissimilar substrate 11 may include one layer or three or more layers. In the case of a single layer or two or more layers, the substrate 13 is not particularly limited, but a metal, Si, silicon carbide (SiC), or the like can be used. In the dissimilar substrate 11, the positions of the substrate 13 and the layer 14 may be reversed, that is, the substrate 13 may be formed on the layer 14.

The resistivity of the nitride layer 12 is 10 Ω·cm or less, preferably 8 Ω·cm or less, more preferably 7 Ω·cm or less, and still more preferably 0.01 Ω·cm or less. In this case, when a semiconductor device is manufactured by forming an epitaxial layer on the nitride layer 12, quality can be improved.

The nitride layer 12 is not particularly limited as long as it is composed of a nitride, for example, AlₓIn_{y}Ga_{(1-x-y)}N (0≦x≦1, 0≦y≦1, 0≦x+y≦1), preferably gallium nitride (GaN), aluminum nitride (AlN), or the like.

The nitride layer 12 has a principal surface 12a and a back surface 12b opposite to the principal surface 12a. The back surface 12b is in contact with the dissimilar substrate 11. The principal surface 12a of the semiconductor substrate 10 is preferably a Ga atomic plane. Further, the principal surface 12a is more preferably a (0001) plane, i.e., a plane (Ga atomic plane) in which Ga atoms are exposed, and the back surface 12b is more preferably a (000-1) plane, i.e., a place (N atomic plane) in which N atoms are exposed. When an epitaxial layer is formed on the Ga atomic plane, the epitaxial layer having improved characteristics can be formed.

The principal surface 12a of the nitride layer 12 is not limited to the (0001) plane but may be a place with an off angle from the (0001) plane, and may be {1-100} plane, a {11-20} plane, or the like.

The thickness of the nitride layer 12 is preferably smaller than that of the dissimilar substrate 11. In this case, the cost of the semiconductor substrate 10 can be decreased by decreasing the thickness of the expensive nitride layer 12. The thickness of the nitride layer 12 is, for example, 100 nm or more and 900 nm or less.

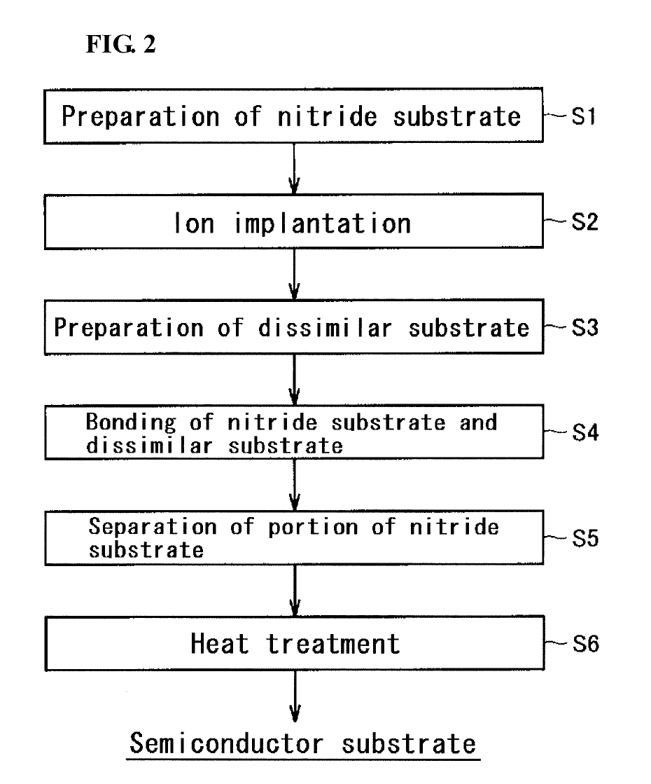

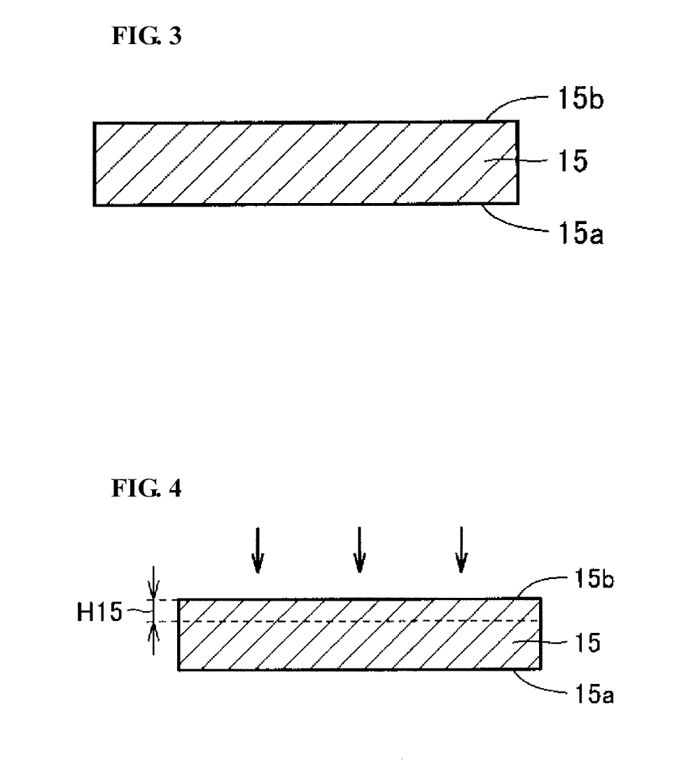

Then, a method for manufacturing the semiconductor substrate 10 of the first embodiment is described. As shown in FIGS. 2 and 3, first, a nitride substrate 15 having a principal surface 15a and a back surface 15b opposite to the principal surface 15a is prepared (Step S1). The principal surface 15a is preferably a (0001) plane, i.e., a Ga atomic plane, and the back surface 15b is preferably a (000-1) plane, i.e., a N atomic plane.

The nitride substrate 15 prepared is, for example, an AlₓIn_{y}Ga_{(1-x-y)}N (0≦x≦1, 0≦y≦1, 0≦x+y≦1), preferably a GaN substrate, an AlN substrate, or the like.

Next, as shown in FIGS. 2 and 4, ions of a light element are implanted into the back surface 15b of the nitride substrate 15 (Step S2). In this Step S2, ions are implanted from the back surface 15b of the nitride substrate 15. Therefore, a region containing a large amount of impurities can be formed near the back surface 15b of the nitride substrate 15. The region containing a large amount of impurities is a fragile region.

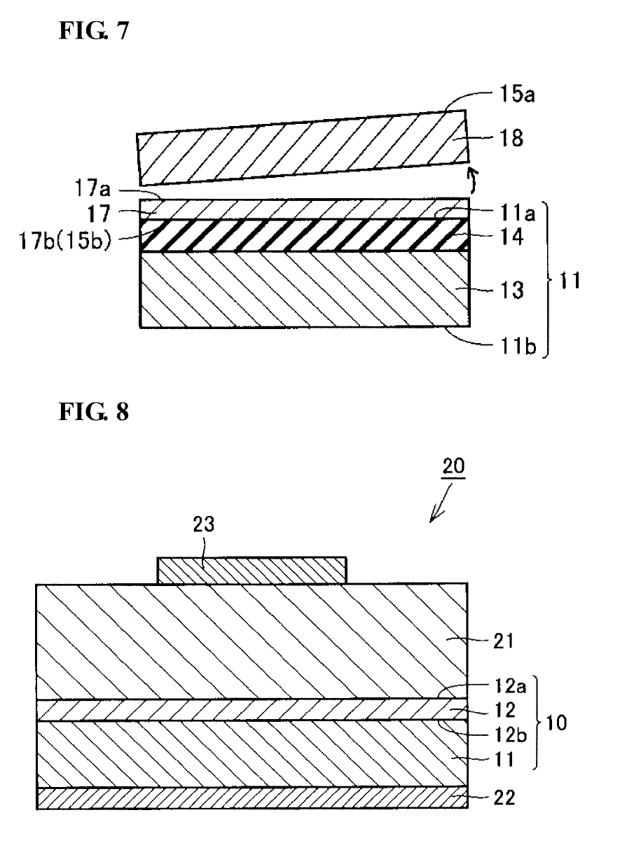

In the Step S2, the ions are preferably implanted in a dose of 1×10¹⁷ cm⁻² or more and 1×10¹⁸ cm⁻² or less, and more preferably 1×10¹⁷ cm⁻² or more and 8×10¹⁷ cm⁻² or less. Since the region implanted with ions at 1×10¹⁷ cm⁻² or more is fragile, a portion of the nitride substrate can be easily separated. On the other hand, in a dose of 1×10¹⁸ cm⁻² or less, the nitride layer 12 (refer to FIGS. 7 and 1) with lower resistance can be formed in Step S6 of heat treatment described below. In addition, separation of a portion of the nitride substrate 15 can be suppressed at the time of ion implantation.

In a dose of 8×10¹⁷ cm⁻² or less, the nitride layer 12 with lower resistance can be formed. From this viewpoint, the dose is more preferably 2×10¹⁷ cm⁻² or more and 7×10¹⁷ cm⁻² or less.

The dose represents the maximum value in the nitride substrate 15. For example, the dose is maximized in a region from a depth H15 (shown by a dotted line in FIG. 4) to the back surface 15b of the nitride substrate 15.

The ions implanted are not particularly limited as long as the ions are vapor-phase ions at 0° C. under the atmospheric pressure, and for example, hydrogen ions (H⁺), helium ions (He⁺), nitrogen ions (N⁻), or the like can be used.

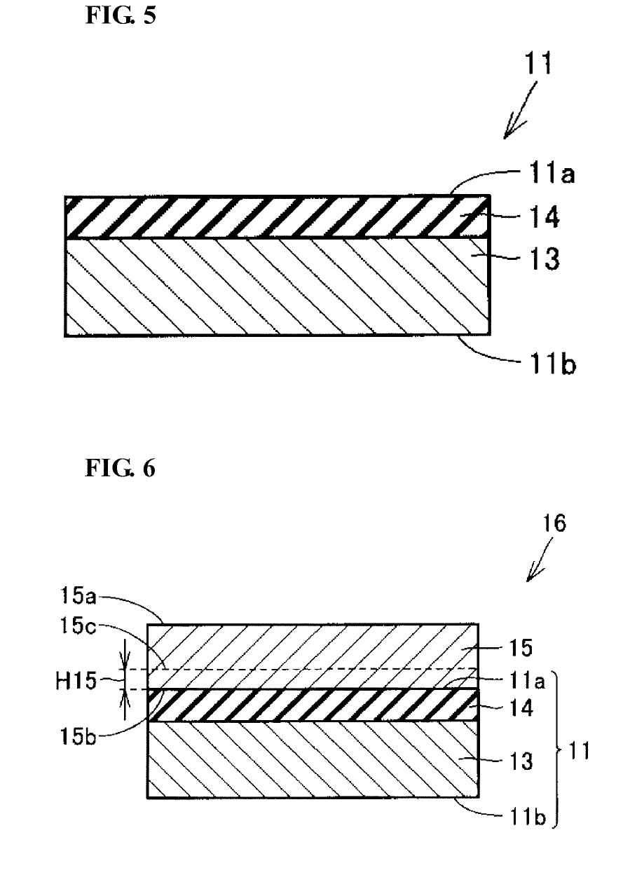

Next, as shown in FIGS. 2 and 5, the dissimilar substrate 11 is prepared (Step S3). The dissimilar substrate 11 is not particularly limited and may include one layer or plural layers. In this embodiment, the dissimilar substrate 11 including the substrate 13 and the layer 14 formed on the substrate 13 is prepared. For example, the dissimilar substrate 11 including a Si substrate as the substrate 13 and a SiO₂ layer as the layer 14 is prepared. As the substrate 13, a metal substrate, a single-crystal SiC substrate, a polycrystalline SiC substrate, a polycrystalline AlN substrate, or the like can be used. For the metal substrate, Mo (molybdenum), W (tungsten), or the like is preferably used. In addition, in the case of one layer, the same material as the substrate 13 is preferably used. Also, the dissimilar substrate 11 including the layer 14 and the substrate 13 formed on the layer 14 may be prepared.

Next, as shown in FIGS. 2 and 6, the back surface 15b of the nitride substrate 15 is bonded to the dissimilar substrate 11 to form a bonded substrate 16 (Step S4). In this embodiment, the back surface 15b of the nitride substrate 15 is bonded in contact with the layer 14 (principal surface 11a) of the dissimilar substrate 11.

The bonding method is not particularly limited, and a method of bonding by pressing in the air can be used. As shown in FIG. 6, this bonding can form the bonded substrate 16 including the dissimilar substrate 11 and the nitride substrate 15 formed on the dissimilar substrate 11.

Next, as shown in FIGS. 2 and 7, a portion of the nitride substrate 15 is separated from the bonded substrate 16 (Step S5).

As a separation method, for example, the nitride substrate 15 can be divided, by heat-treating the bonded substrate 16, at a boundary phase between the fragile region (region from the depth H15 to the back surface in FIG. 6) and a portion of the nitride substrate 15 which is a portion of the GaN substrate other than the fragile region. The separation method is not particularly limited, and for example, a method of applying stress, a method of irradiating light, or the like may be used.

As a result, a laminated substrate including the dissimilar substrate 11 and a nitride layer 17 formed on the dissimilar substrate 11 can be formed. The nitride layer 17 has a principal surface 17a and a back surface 17b opposite to the principal surface 17a, and the back surface 17b of the nitride layer 17 coincides with the back surface 15b of the nitride substrate 15. Consequently, a portion (nitride layer 18) of the expensive nitride substrate 15 can be separated and recycled, and only the residue (nitride layer 17) can be used, thereby decreasing the manufacturing cost.

Next, as shown in FIG. 2, the laminated substrate is heat-treated at a temperature over 700° C. (Step S6). As a result, the resistance of the nitride layer 17 as a residue of the nitride substrate 15 can be decreased. The nitride layer 17 becomes the nitride layer 12 (refer to FIG. 1) having a resistivity of 10 Ω·cm or less.

The heat treatment temperature is preferably over 700° C. and 1500° C. or less and more preferably 900° C. or more and 1200° C. or less. The heat treatment at a temperature over 700° C. can facilitate the removal of ions of the light element implanted in Step S2. The heat treatment at a temperature of 900° C. or more can further facilitate the removal of ions of the light element implanted in Step S2. On the other hand, the heat treatment at a temperature of 1500° C. or less can suppress deterioration of the nitride layer 12 due to the heat treatment. The heat treatment at a temperature of 1200° C. or less can further suppress deterioration of the nitride layer 12.

The higher the heating rate to the temperature of heat treatment, the more easily the ions implanted in Step S2 diffuse. That is, the ions implanted can be easily removed, thereby increasing the effect of decreasing the resistance of the nitride layer 12. From this viewpoint, the heating rate is preferably 10° C./min or more, more preferably 20° C./min or more, and still more preferably 25° C./min or more.

The atmosphere of heat treatment is not particularly limited, but an atmosphere containing nitrogen (N) atoms is preferred. The atmosphere containing nitrogen (N) atoms represents a gas containing N atoms, for example, an atmosphere containing nitrogen gas (N₂), ammonia gas (NH₃), or the like. In this case, N atoms constituting the nitride layer 12 can be suppressed from being eliminated due to weakening of bonds to other atoms during the heat treatment. Therefore, a decrease in quality of the nitride layer 12 can be suppressed.

From the viewpoint of suppressing the elimination of N atoms, the atmosphere of the heat treatment preferably contains ammonia gas. This is because ammonia gas easily supplies active nitrogen. When ammonia gas is contained, a partial pressure of ammonia gas is preferably 1×10⁻⁴ atm (10.13 Pa) or more and 1 atm (1013 hPa) or less, and more preferably 0.05 atm or more and 0.25 atm or less.

The heat treatment may be performed in a separate apparatus before the laminated substrate is placed in an epitaxial layer forming apparatus for forming an epitaxial layer. However, the heat treatment is preferably performed in the epitaxial layer forming apparatus immediately before the epitaxial layer is formed because the number of steps is decreased. The epitaxial layer forming apparatus is not particularly limited but is, for example, an OMVPE (Organo Metallic Vapor Phase Epitaxy) apparatus.

When the heat treatment is performed in the OMVPE apparatus, the heat treatment time is preferably 5 minutes or more, more preferably 10 minutes or more, longer than that in an apparatus other than the OMVPE apparatus. The reason for this is that the heat treatment time is shorter by a time corresponding to a cooling time than that of heat treatment using an apparatus other than the OMVPE apparatus.

The semiconductor substrate 10 shown in FIG. 1 can be manufactured through the above-described Steps S1 to S6. When the semiconductor substrate 10 is used for a semiconductor device, for example, it can be used as a horizontal semiconductor device. Alternatively, when the semiconductor substrate 10 includes an insulating layer 14, a step of removing the layer 14 may be further performed.

As described above, according to the method for manufacturing the semiconductor substrate 10 of the first embodiment, heat treatment is performed (Step S6) after ions of a light element are implanted for forming a fragile region (Step S2). Since the ions implanted in Step S2 are of a light element, the ions are easily removed, by heat treatment in Step S6, from the nitride layer 17 bonded to the dissimilar substrate 11 without being separated from the nitride substrate 15. In addition, as a result of keen research of heat treatment conditions for easily removing ions from the nitride layer 17, the inventors have found that the heat treatment is performed at a temperature over 700° C. In this case, removal of the ions implanted in Step S2 from the nitride substrate 15 (nitride layer 17) can be promoted, and thus the resistance of the nitride layer 17 bonded to the dissimilar substrate 11 without being separated from the bonded substrate 16 can be decreased. Therefore, the semiconductor substrate 10 including the low-resistance nitride layer 12 can be manufactured.

The semiconductor substrate 10 manufactured as described above includes the nitride layer 12 having a resistivity of, for example, 10 Ω·cm or less. When a semiconductor device is formed by forming an epitaxial layer on the nitride layer 12, complication of a chip structure can be suppressed, and a decrease in breakdown voltage can be suppressed, thereby improving quality.

### Second Embodiment

A Schottky barrier diode (SBD) 20 serving as a semiconductor device according to a second embodiment is described with reference to FIG. 8. As shown in FIG. 8, the SBD 20 includes a semiconductor substrate 10, an epitaxial layer 21 formed on the semiconductor substrate 10, an electrode 22 formed on a back surface of the semiconductor substrate 10, and a Schottky electrode 23 formed on the epitaxial layer 21.

The semiconductor substrate 10 is basically the same as the semiconductor substrate 10 of the first embodiment but uses a dissimilar substrate 11 of a conductive material. In this embodiment, for example, a conductive substrate is used as the dissimilar substrate 11. As the dissimilar substrate 11, a Mo substrate, a W substrate, or the like is preferably used. The dissimilar substrate 11 may include one layer or plural layers.

The epitaxial layer 21 is formed on a principal surface 12a of a nitride layer 12 constituting the semiconductor substrate 10. The epitaxial layer 21 is, for example, a drift layer. The epitaxial layer 21 is preferably a nitride semiconductor layer, for example, an AlₓIn_{y}Ga_{(1-x-y)}N (0≦x≦1, 0≦y≦1, 0≦x+y≦1) layer, such as a GaN layer or the like. The epitaxial layer 21 preferably has the same composition as the nitride layer 12 constituting the semiconductor substrate 10.

The electrode 22 is formed below the dissimilar substrate 11 constituting the semiconductor substrate 10. The electrode 22 is, for example, an ohmic electrode. The Schottky electrode 23 is formed on the epitaxial layer 21.

Then, a method for manufacturing the Schottky barrier diode 20 of this embodiment is described.

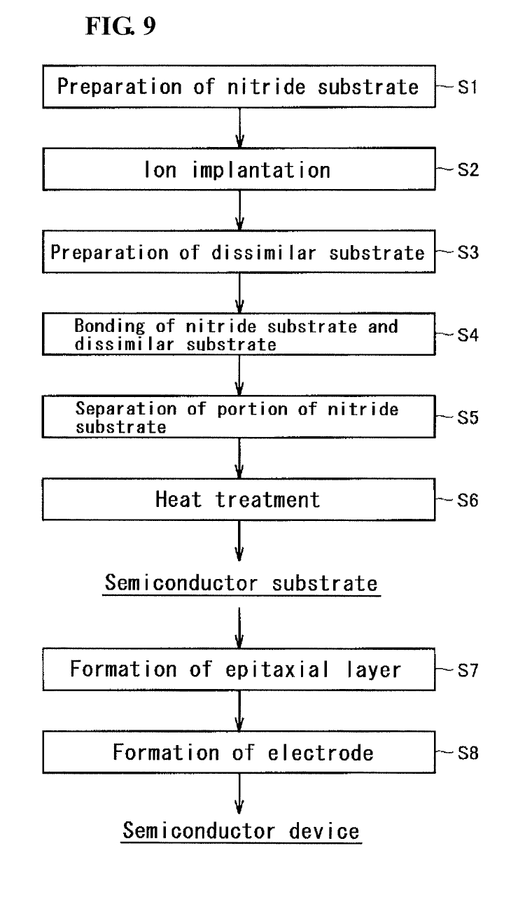

First, as shown in FIG. 9, according to the method for manufacturing the semiconductor substrate 10 of the first embodiment, the semiconductor substrate 10 shown in FIG. 1 is produced (Steps S1 to S6). In this embodiment, the conductive dissimilar substrate 11 is prepared.

Next, as shown in FIG. 9, the epitaxial layer 21 is formed on the semiconductor substrate 10 (Step S7). In this embodiment, the epitaxial layer 21 is formed on the principal surface 12a of the nitride layer 12 constituting the semiconductor substrate 10.

In Step S7, the epitaxial layer 21 composed of, for example, AlₓIn_{y}Ga_{(1-x-y)}N (0≦x≦1, 0≦y≦1, 0≦x+y≦1) is formed. The epitaxial layer 21 may include one layer or plural layers.

In addition, the epitaxial layer 21 having the same composition as the nitride layer 12 constituting the semiconductor substrate 10 is preferably formed. In this case, the epitaxial layer 21 having improved characteristics can be formed because the problem of lattice mismatch can be alleviated.

The method for forming the epitaxial layer 21 is not particularly limited, and a vapor-phase growth method such as a HVPE (Hydride Vapor Phase Epitaxy) method, a MBE (Molecular Beam Epitaxy) method, an OMVPE method, a sublimation method, or the like, or a liquid phase method such as a flux method, a high-nitrogen-pressure melt method, or the like can be used. As a result, an epitaxial wafer including the semiconductor substrate 10 and the epitaxial layer 21 formed on the semiconductor substrate 10 can be manufactured.

Next, the electrode 22 is formed on the side opposite to the surface on which the epitaxial layer 21 is formed in the semiconductor substrate 10, i.e., on the dissimilar substrate 11 side. As the electrode 22, for example, an ohmic electrode is formed. Next, the Schottky electrode 23 is formed on the epitaxial layer 21 (Step S8). The method of forming the Schottky electrode 23 and the electrode 22 and the order of the formation of the electrodes are not particularly limited, and the electrodes are formed by, for example, an evaporation method.

The Schottky barrier diode 20 shown in FIG. 8 can be manufactured through the above-described Steps S1 to S8.

As described above, according to the method for manufacturing the SBD 20 as a semiconductor device of this embodiment and the SBD 20, since the epitaxial layer 21 is formed on the semiconductor substrate including the low-resistance nitride layer 12, a chip structure can be prevented from being complicated, and a decrease in breakdown voltage can be suppressed, so that the SBD 20 with improved quality can be realized.

In particular, when the resistivity of the nitride layer 12 constituting the semiconductor substrate 10 is 10 Ω·cm or less, the quality of the SBD 20 can be effectively improved.

Although, in this embodiment, the SBD is described as an example of a semiconductor device, the semiconductor device of the present invention is not limited to SBD, and the present invention can be applied to LED (Light Emitting Diode), LD (Laser Diode), MOSFET (Metal Oxide Semiconductor Field Effect Transistor), JFET (Junction Field-Effect Transistor), a pn diode, IGBT (Insulated Gate Bipolar Transistor), and the like.

### Example 1

In this example, the effect of decreasing resistance by heat treatment at a temperature over 700° C. was examined.

### Invention Examples 1 to 22

Semiconductor substrates of Invention Examples 1 to 22 were manufactured basically according to the method for manufacturing the semiconductor substrate of the first embodiment.

Specifically, first, in Step S1 of preparing the nitride substrate 15, as shown in FIG. 3, a GaN substrate doped with oxygen and having a principal surface 15a and a back surface 15b, which were made specular by polishing, and a diameter of 2 inches (5.08 cm) and a thickness of 500 μm was prepared. The GaN substrate had a resistivity of 1 Ω·cm or less and a carrier concentration of 1×10¹⁷ cm⁻³ or more. In addition, the principal surface 15a was a Ga atomic plane, and the back surface 15b was a N atomic plane.

Next, in Step S2 of implanting ions, hydrogen ions were implanted into the back surface 15b (N atomic plane) of the prepared GaN substrate. The hydrogen ions were implanted at an acceleration voltage of 180 keV in a dose of 1×10¹⁷ cm⁻² or more and 8×10¹⁷ cm⁻² or less as shown Table I. The dose was considered to be the maximum concentration in a region implanted with hydrogen ions. In Invention Examples 1 to 22, the dose of hydrogen ions implanted was maximized in a region from the back surface 15b to a depth H15 (refer to FIG. 4) of about 1 μm from the N atomic plane.

Then, the back surface 15b (N atomic plane) implanted with hydrogen ions in the GaN substrate was washed. Next, the back surface 15b was made clean by a dry etching apparatus using plasma generated by discharge in argon (Ar) gas. The plasma generation conditions for cleaning the back surface 15b of the GaN substrate included a RF power of 100 W, an Ar gas flow rate of 50 sccm (volume of gas flowing per minute under standard conditions (cm³/min)), and a pressure of 6.7 Pa.

Next, in Step S3 of preparing a dissimilar substrate, a dissimilar substrate 11 including a Si substrate and a SiO₂ layer of 100 nm in thickness formed on a surface by thermal oxidation of the Si substrate, i.e., a Si substrate (substrate 13) including a SiO₂ layer (layer 14) formed thereon as shown in FIG. 5, was prepared. Next, the principal surface 11a of the dissimilar substrate 11 was made cleans by a dry etching apparatus using plasma generated by discharge in Ar gas. The plasma generation conditions for cleaning the principal surface 11a of the dissimilar substrate 11 were the same as for the back surface 15b of the GaN substrate.

Next, in Step S4 of bonding the back surface of the nitride substrate to the dissimilar substrate to form the bonded substrate 16, the clean surfaces, i.e., the back surface 15b (N atomic plane) of the GaN substrate and the principal surface 11a of the Si substrate (dissimilar substrate 11) including the SiO₂ layer formed thereon, were bonded together in air. As a result, the bonded substrate 16 shown in FIG. 6 was produced.

Next, in Step S5 of separating a portion of the nitride substrate, the bonded substrate was heat-treated at 300° C. to 500° C. for 2 to 5 hours in a N₂ gas atmosphere. In this heat treatment, the bonding strength was enhanced, and the GaN substrate was divided at the depth H15 of about 1 μm from the back surface 15b of the GaN substrate. Namely, the GaN substrate was divided at between a region in which the dose of ion implanted in Step S2 was maximized and a portion of the GaN substrate other than the region. As a result, as shown in FIG. 7, a laminated substrate having a GaN layer of about 1 μm in thickness as the nitride layer 17 was formed.

Next, in Step S6 of heat treatment, the bonded substrate (laminated substrate) having the GaN layer was heat-treated with a heat treatment apparatus under the conditions shown in Table I below. Namely, the substrate was maintained at 1 atm (1013 hPa), a temperature exceeding 700° C. shown in Table I below, and a heating rate of 10° C./min in an atmosphere gas shown in Table I below for a time of 5 minutes or more and 180 minutes or less shown in Table I below.

The semiconductor substrates 10 of Invention Examples 1 to 22 shown in FIG. 1 were manufactured through the above-described Steps S1 to S6.

### Comparative Examples 1 and 2

A method for manufacturing semiconductor substrates in Comparative Examples 1 and 2 was basically the same as the method for manufacturing the semiconductor substrates in Invention Examples 1 to 22 but was different in that in Step S6 of heat treatment, heat treatment was performed at 700° C.

### Comparative Example 3

A method for manufacturing a semiconductor substrate in Comparative Example 3 was basically the same as the method for manufacturing the semiconductor substrates in Invention Examples 1 to 22 but was different in that Step S6 of heat treatment was not performed.

### (Measurement Method)

The resistivity of the GaN layer of each of Invention Examples 1 to 22 and Comparative Examples 1 to 3 was determined by a four-probe method and a hole measurement method. The results are shown in Table I below.

TABLE I

| | Heat treatment step (S6) | | | | Ion implantation | |
|---|---|---|---|---|---|---|
| | | | | Ammonia | step(S2) | |
| | Temperature | Time | Atmosphere | concentration | Dose | Resistivity |
| | (° C.) | (min) | gas | (atm) | (cm⁻²) | (Ωcm) |
| Invention Example 1 | 1050 | 30 | N₂ | 0 | 3 × 10¹⁷ | 0.01 |
| Invention Example 2 | 900 | 30 | N₂ | 0 | 3 × 10¹⁷ | 7 |
| Invention Example 3 | 1000 | 30 | N₂ | 0 | 3 × 10¹⁷ | 0.1 |
| Invention Example 4 | 1200 | 30 | N₂ | 0 | 3 × 10¹⁷ | 0.01 |
| Invention Example 5 | 1050 | 30 | N₂ | 0 | 1 × 10¹⁷ | 0.007 |
| Invention Example 6 | 1050 | 30 | N₂ | 0 | 2 × 10¹⁷ | 0.009 |
| Invention Example 7 | 1050 | 30 | N₂ | 0 | 8 × 10¹⁷ | 8 |
| Invention Example 8 | 1050 | 5 | N₂ | 0 | 3 × 10¹⁷ | 0.5 |
| Invention Example 9 | 1050 | 10 | N₂ | 0 | 3 × 10¹⁷ | 0.35 |
| Invention Example 10 | 1050 | 15 | N₂ | 0 | 3 × 10¹⁷ | 0.2 |
| Invention Example 11 | 1050 | 60 | N₂ | 0 | 3 × 10¹⁷ | 0.01 |
| Invention Example 12 | 1050 | 120 | N₂ | 0 | 3 × 10¹⁷ | 0.01 |
| Invention Example 13 | 1050 | 180 | N₂ | 0 | 3 × 10¹⁷ | 0.009 |
| Invention Example 14 | 1050 | 30 | N₂ + NH₃ | 0.05 | 3 × 10¹⁷ | 0.01 |
| Invention Example 15 | 1050 | 30 | N₂ + NH₃ | 0.1 | 3 × 10¹⁷ | 0.01 |
| Invention Example 16 | 1050 | 30 | N₂ + NH₃ | 0.25 | 3 × 10¹⁷ | 0.01 |
| Invention Example 17 | 1050 | 30 | H₂ | 0 | 3 × 10¹⁷ | 0.01 |
| Invention Example 18 | 1050 | 30 | H₂ + NH₃ | 0.05 | 3 × 10¹⁷ | 0.01 |
| Invention Example 19 | 1050 | 30 | H₂ + NH₃ | 0.1 | 3 × 10¹⁷ | 0.01 |
| Invention Example 20 | 1050 | 30 | H₂ + NH₃ | 0.25 | 3 × 10¹⁷ | 0.01 |
| Invention Example 21 | 800 | 180 | N₂ | 0 | 3 × 10¹⁷ | 0.02 |
| Invention Example 22 | 900 | 60 | N₂ | 0 | 3 × 10¹⁷ | 0.01 |
| Comparative Example 1 | 700 | 30 | N₂ | 0 | 3 × 10¹⁷ | 12 |
| Comparative Example 2 | 700 | 180 | N₂ | 0 | 3 × 10¹⁷ | 12 |
| Comparative Example 3 | — | 0 | — | — | 3 × 10¹⁷ | 100 or more |

### (Measurement Results)

Table I indicates that the GaN layers formed as nitride layers constituting the respective semiconductor substrates in Invention Examples 1 to 22 undergoing step S6 in which heat treatment was performed at a temperature exceeding 700° C. have a resistivity of as low as 0.007 Ω·cm or more and 8 Ω·cm or less.

On the other hand, the GaN layers constituting the respective semiconductor substrates in Comparative Examples 1 and 2 in which heat treatment was performed at 700° C. have a resistivity of 12 Ω·cm which is larger than in Invention Examples 1 to 22. In addition, the GaN layer constituting the semiconductor substrate in Comparative Example 3 in which heat treatment was not performed has a resistivity of 100 Ω·cm or more which exceeds measurable resistivity.

Therefore, it could be confirmed that the resistivity of a nitride layer constituting a semiconductor substrate can be decreased by heat treatment at a temperature over 700° C. Although, in this example, a GaN layer is described as an example of a nitride layer, the inventors have found that a semiconductor substrate including a nitride layer with the same resistivity can be manufactured using a nitride substrate.

Further, in Invention Examples 14 to 16 and 18 to 20 in which heat treatment was performed in an atmosphere containing ammonia in Step S6, the removal of N atoms from the GaN layers constituting the respective semiconductor substrates was suppressed, and thus Ga droplets of Ga atom alone were not formed. In addition, in Invention Examples 1 to 13, 21, and 22 in which heat treatment was performed in an atmosphere containing N atom without containing ammonia, N atoms were removed from a portion of a surface of each GaN layer, and thus Ga droplets were formed in a portion of each surface. Further, in Invention Example 17 in which heat treatment was performed in an atmosphere not containing N atoms, N atoms were removed from most of the surfaces of the GaN layers, and thus Ga droplets were formed in most part of the surfaces. However, the inventors found that in heat treatment in an atmosphere not containing N atoms, the formation of Ga droplets can be suppressed by shortening the heat treatment time.

Therefore, it was found that a surface of a nitride layer can be maintained in good conditions by heat treatment in an atmosphere containing N atoms. In particular, it was found that in order to maintain a surface of a nitride layer in good conditions, heat treatment in an atmosphere containing ammonia is effective.

In addition, it was found that when a dose is 1×10¹⁷ cm⁻² or more in Step S2 of ion implantation, separation in Step S5 can be easily performed. Further, it was found that when a dose is 1×10¹⁸ cm⁻² or less in Step S2 of ion implantation, separation can be suppressed during ion implantation. Namely, it was found that when a dose is 1×10¹⁷ cm⁻² or more and 1×10¹⁸ cm⁻² or less in Step S2 of ion implantation, a bonded substrate including a dissimilar substrate and a nitride layer formed on the dissimilar substrate can be easily formed.

### Example 2

In this example, the effect of Step S6 of heat treatment in an epitaxial layer forming apparatus for forming an epitaxial layer was examined.

### Invention Examples 23 to 25

In Invention Examples 23 to 25, a method for manufacturing a semiconductor substrate was basically the same as in Invention Examples 1 to 22 but was different in that in Invention Examples 1 to 22, a heat treatment apparatus other than an OMVPE apparatus was used, while in Invention Examples 23 to 25, an OMVPE was used. The detail conditions are shown in Table II below.

### (Measurement Method)

The resistivity of the GaN layer of each of Invention Examples 23 to 25 was determined by the same four-probe method and hole measurement method as in Example 1. The results are shown in Table II below.

TABLE II

| | Heat treatment step (S6) | | | | Ion implantation | |
|---|---|---|---|---|---|---|
| | | | | Ammonia | step(S2) | |
| | Temperature | Time | Atmosphere | concentration | Dose | Resistivity |
| | (° C.) | (min) | gas | (atm) | (cm⁻²) | (Ωcm) |
| Invention Example 23 | 1050 | 30 | N₂ | 0 | 3 × 10¹⁷ | 0.02 |
| Invention Example 24 | 1050 | 35 | N₂ | 0 | 3 × 10¹⁷ | 0.015 |
| Invention Example 25 | 1050 | 40 | N₂ | 0 | 3 × 10¹⁷ | 0.01 |

### (Measurement Results)

Tables I and II indicate that in Invention Examples 23 to 25 in which heat treatment was performed at a temperature over 700° C. in an OMVPE apparatus, the resistivity of nitride layers constituting the respective semiconductor substrates can be more decreased than in Comparative Examples 1 to 3. Thus, it was found that even when heat treatment is performed with an OMVPE apparatus for forming an epitaxial layer in Step S6, the resistivity of a nitride layer constituting a semiconductor substrate can be decreased. Therefore, the resistivity of a nitride layer constituting a semiconductor substrate can be decreased by heat treatment in Step S6 using the same apparatus as an epitaxial layer forming apparatus for forming an epitaxial layer. Thus, it cloud be confirmed that the number of steps for forming an epitaxial wafer or a semiconductor device can be decreased.

### Example 3

In this example, the effect of a heating rate to the heat treatment temperature in Step S6 of heat treatment was examined.

### Invention Examples 26 and 27

In Invention Examples 26 and 27, a method for manufacturing a semiconductor substrate was basically the same as in Invention Examples 23 to 25 but was different in that in Invention Examples 23 to 25, the heating rate was 10° C./min, while in Invention Examples 26 and 27, the heating rate was 20° C./min. The detailed conditions are shown in Table III below.

### (Measurement Method)

The resistivity of the GaN layer of each of Invention Examples 26 and 27 was determined by the same four-probe method and hole measurement method as in Example 1. The results are shown in Table III below.

TABLE III

| | Heat treatment step (S6) | | | | | Ion implantation | |
|---|---|---|---|---|---|---|---|
| | | | | | Ammonia | step(S2) | |
| | Temperature | Time | Heating rate | Atmosphere | concentration | Dose | Resistivity |
| | (° C.) | (min) | (° C./min) | gas | (atm) | (cm⁻²) | (Ωcm) |
| Invention Example 26 | 1050 | 30 | 20 | N₂ | 0 | 3 × 10¹⁷ | 0.004 |
| Invention Example 27 | 1050 | 35 | 20 | N₂ | 0 | 3 × 10¹⁷ | 0.002 |

### (Measurement Results)

Tables I and III indicate that in Invention Examples 26 and 275 in which heat treatment was performed at a temperature over 700° C. in an OMVPE apparatus, the resistivity of nitride layers constituting the respective semiconductor substrates can be more decreased than in Comparative Examples 1, 2 and 3.

Also, Tables II and III indicate that in Invention Examples 26 and 27 in which the heating rate was 20° C./min, the resistivity can be more decreased than in Invention Examples 23 and 24 in which the heating rate was 10° C./min. According to Examples 2 and 3, it could be confirmed that the resistivity of a nitride layer constituting a semiconductor layer can be further decreased by heating to the heat treatment temperature at a heating rate of preferably 10° C./min or more and more preferably 20° C./min or more in heat treatment (Step S6).

### Example 4

In this example, the effect of manufacture of a semiconductor device using a semiconductor substrate including a nitride layer with small resistivity was examined.

### Invention Example 28

In Invention Example 28, SBD 20 shown in FIG. 8 was basically manufactured as a semiconductor device according to the method for manufacturing a semiconductor device of the second embodiment.

Specifically, first, a semiconductor substrate was manufactured. In Invention Example 28, a method for manufacturing a semiconductor substrate was basically the same as in Invention Example 7 but was different only in that a Mo substrate without a SiO₂ layer formed thereon was used as the dissimilar substrate 11. The resistivity of the semiconductor substrate 10 of Invention Example 28 was 8 Ω·cm.

Next, in Step S7 of forming an epitaxial layer 21, the epitaxial layer 21 was formed on a GaN layer constituting the semiconductor substrate 10 by the OMVPE method. The epitaxial layer 21 was an n-type GaN layer having a carrier concentration of 7×10¹⁵ cm⁻³ and a thickness of 5 μm.

Next, in Step S8 of forming an electrode, an electrode 22 was formed on the back surface of the Mo substrate constituting the semiconductor substrate 10, and a Schottky electrode 23 was formed on the epitaxial layer 21. The Schottky electrode 23 included a gold film formed by a resistance-heating evaporation method. The Schottky electrode 23 was a circular electrode having a diameter of 200 μm.

Before each of the electrode 22 and the Schottky electrode 23 was formed, the back surface of the Mo substrate was protected before evaporation, and then the front surface of the epitaxial layer 21 and the back surface (the dissimilar substrate 11) of the semiconductor substrate 10 were treated with an aqueous HCl (hydrochloric acid) solution (hydrochloric acid 1:pure water 1) at room temperature for 1 minute.

### Invention Example 29

In Invention Example 29, a method for manufacturing SBD was basically the same as in Invention Example 28 except that the shape of a Schottky electrode was different. Specifically, a square Schottky electrode 23 having a side of 4500 μm was formed, and the corners were rounded with 20 μmR to prevent electric field concentration at reverse bias.

### Comparative Examples 4 and 5

In Comparative Examples 4 and 5, a method for manufacturing SBD was basically the same as in Invention Examples 28 and 29 but was different in that the method for manufacturing a semiconductor substrate was different. Specifically, Step S6 of heat treatment was not performed. Therefore, the resistivity of the semiconductor substrates used in Comparative Examples 4 and 5 exceeded 100 Ω·cm.

### Comparative Examples 6 and 7

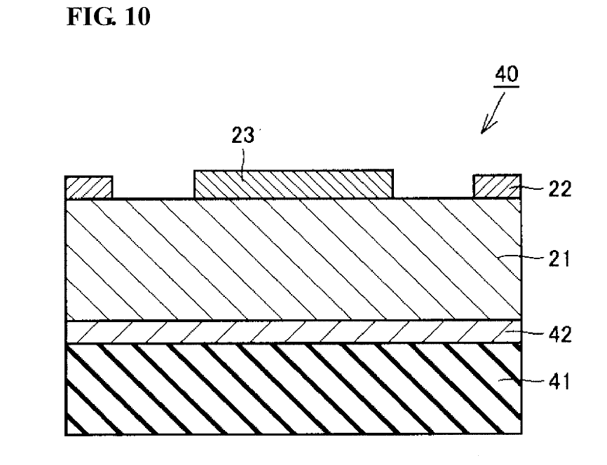

In Comparative Examples 6 and 7, a method for manufacturing SBD 40 was basically the same as in Invention Examples 28 and 29 except that a sapphire substrate 41 was used in place of the semiconductor substrate. Specifically, as shown in FIG. 10, a buffer layer 42 composed of GaN was formed on the sapphire substrate 41, and an epitaxial layer 21 was formed on the buffer layer 42. Since the sapphire substrate 41 was insulating, an electrode 22 was formed on the epitaxial layer 21.

### (Measurement Method)

The breakdown voltage, current density, current, on-resistance, and forward voltage of SBD of each of Invention Examples 28 and 29 and Comparative Examples 4 to 7 were measured. These were measured by a current-voltage measurement method.

### (Measurement Results)

The SBD of Invention Example 28 including a circular (200 μm in diameter) Schottky electrode with a diameter of 200 μm showed a breakdown voltage of 600 V, a current density of 500 A/cm², a current of 0.15 A, an on-resistance of 3.3 mΩ. and a forward voltage of 1.5 V. In Comparative Example 4 using a Schottky electrode of the same shape, the on-resistance was very higher than that in Invention Example 28, and good device characteristics could not be obtained. In Comparative Example 6 using a Schottky electrode of the same shape, the on-resistance and forward voltage were higher than that in Invention Example 28, and the breakdown voltage was as low as 100 V.

The reason why the on-resistance of Comparative Example 4 is higher than that in Invention Example 28 is possibly that the GaN layer constituting the semiconductor substrate has very high resistivity.

The reason why the on-resistance and forward voltage are increased in Comparative Example 6 is possibly that the ohmic electrode is formed on the epitaxial layer 21, thereby increasing resistance in a transverse direction. In addition, the reason why the breakdown voltage is low in Comparative Example 6 is possibly that the GaN layer is formed on the dissimilar substrate, thereby increasing the dislocation density.

In the SBD of Invention Example 29 including the square Schottky electrode with a side of 4500 μm, differences in characteristics were increased as compared with Invention Example 28 including the small Schottky electrode with 200 μm in diameter. In Invention Example 29, substantially no decrease in breakdown voltage was observed even when the size of the Schottky electrode was increased, and forward characteristics such as a current density of 500 A/cm², a current of 100 A, an on-resistance of 5 mΩ, and a forward voltage of 1.5 V, which are good characteristics expected from a small-area electrode, could be achieved.

In Comparative Example 7 including the Schottky electrode with the same shape and the sapphire substrate, a current of only 50 A could be flowed even at an applied voltage of 5 V. This is possibly because a large-area electrode is further influenced by resistance in the transverse direction.

As described above, in this example, SBD ideal as application to electric power devices with a large current, a low on-resistance, and high breakdown voltage can be realized by using a semiconductor substrate including a GaN layer with a resistivity of as small as 10 Ω·cm or less.

In addition, SBD having the characteristics achieved by using a GaN substrate can be manufactured by bonding a GaN substrate, and the cost can be decreased.

It should be considered that the embodiments and examples disclosed here are exemplary, not limitative, in all respects. The scope of the present invention is indicated by the claims, not the above-described embodiments, and is intended to include meanings equivalent to the claims and any modifications within the scope.

What is claimed is:

1. A method for manufacturing a semiconductor substrate comprising:
a step of preparing a nitride substrate having a principal surface and a back surface opposite to the principal surface;
a step of implanting ions of a light element into the back surface of the nitride substrate;
a step of bonding the back surface of the nitride substrate to a dissimilar substrate to form a bonded substrate;
a step of separating a portion of the nitride substrate from the bonded substrate to form a laminated substrate including the dissimilar substrate and a nitride layer; and
a step of heat-treating the laminated substrate at a temperature over 700° C.

2. The method for manufacturing a semiconductor substrate according to claim 1, wherein in the heat treatment step, heat treatment is performed at a temperature of 1500° C. or less.

3. The method for manufacturing a semiconductor substrate according to claim 1, wherein the heat treatment step is performed in an atmosphere containing nitrogen atoms.

4. The method for manufacturing a semiconductor substrate according to claim 1, wherein in the ion implantation step, the ions are implanted in a dose of 1×10¹⁷ cm⁻² or more and 1×10¹⁸ cm⁻² or less.

5. A method for manufacturing a semiconductor device comprising:
a step of manufacturing a semiconductor substrate by the method for manufacturing a semiconductor substrate according to claim 1;
a step of forming an epitaxial layer on the semiconductor substrate; and
a step of forming an electrode on the epitaxial layer.

6. A semiconductor substrate comprising:
a dissimilar substrate; and
a nitride layer formed on the dissimilar substrate,
wherein the nitride layer has a resistivity of 10 Ω·cm or less.

7. A semiconductor device comprising:
the semiconductor substrate according to claim 6;
an epitaxial layer formed on the semiconductor substrate; and
an electrode formed on the epitaxial layer.
